(19) United States
(12) Patent Application Publication
(10) Pub. No.: US 2025/0316661 A1
(43) Pub. Date: Oct. 9, 2025

(54) LIGHT EMITTING PANEL AND LIGHT SOURCE DEVICE INCLUDING A LIGHT EMITTING PANEL

(71) Applicant: SAMSUNG DISPLAY CO., LTD., YONGIN-SI (KR)

(72) Inventors: JIWON JUNG, Yongin-si (KR); GUANGHAI JIN, Yongin-si (KR)

(21) Appl. No.: 18/813,790

(22) Filed: Aug. 23, 2024

(30) Foreign Application Priority Data
Apr. 9, 2024 (KR) 10-2024-0047925

(51) Int. Cl. H01L 25/16; H01L 27/12; H01L 33/38; H01L 33/62

(52) U.S. Cl. CPC H01L 25/167; H10D 86/441; H10D 86/60; H10H 20/831; H10H 20/857

(57) ABSTRACT

A light emitting panel includes: a plurality of unit pixels, wherein each of the plurality of unit pixels includes a plurality of sub-pixels. Each of the plurality of sub-pixels includes a pixel electrode that includes a first side extending in a first direction and a second side that extends in a second direction. Each pixel electrode is electrically connected to one or more pixel circuits through a plurality of contact holes. The plurality of contact holes includes one or more first contact holes and a plurality of second contact holes, wherein the one or more first contact holes are arranged along the first side, and the plurality of second contact holes are arranged along the second side. The one or more pixel circuits is connected to one data line and can transmit the same data voltage to the pixel electrode through the plurality of contact holes.

### CROSS-REFERENCE TO RELATED APPLICATION

This application claims priority under 35 U.S.C. § 119 to Korean Patent Application No. 10-2024-0047925 filed at the Korean Intellectual Property Office on Apr. 9, 2024, the disclosure of which is incorporated by reference herein in its entirety.

### TECHNICAL FIELD

The present invention relates to a light emitting panel and a light source device including the same.

### DISCUSSION OF THE RELATED ART

A light emitting panel including a light emitting element may be used, for example, as a display panel to display images and a lighting device or a light source device. The light emitting panel includes a plurality of pixels to emit light. Generally, each pixel includes a pixel electrode that receives a data signal, and the pixel electrode is connected to a pixel circuit to receive a data voltage.

The pixel circuit may generally include at least one transistor that is formed on a substrate.

Various vision devices are currently under development to implement extended reality (XR) such as augmented reality (AR), virtual reality (VR), and mixed reality (MR) or to experience images in various ways. These vision devices may use a light source.

### SUMMARY

According to an embodiment of the present invention, a light emitting panel includes: a plurality of unit pixels, wherein each of the plurality of unit pixels includes a plurality of sub-pixels, each of the plurality of sub-pixels includes a pixel electrode, the pixel electrode has a first side extending in a first direction and a second side that is longer than the first side and extends in a second direction that is different from the first direction, each pixel electrode is electrically connected to one or more pixel circuits through a plurality of contact holes and is configured to receive a data voltage, the plurality of contact holes includes one or more first contact holes and a plurality of second contact holes, wherein the one or more first contact holes are arranged along the first side of the pixel electrode, and the plurality of second contact holes are arranged along the second side of the pixel electrode, wherein a number of second contact holes of the plurality of second contact holes is greater than a number of the one or more first contact holes that are arranged along the first side, and the one or more pixel circuits is connected to one data line and can transmit the same data voltage to the pixel electrode through the plurality of contact holes.

In an embodiment of the present invention, the plurality of sub-pixels each has a light emitting region, and the plurality of contact holes do not overlap the light emitting region.

In an embodiment of the present invention, the pixel electrode includes a rectangular-shaped portion and a plurality of protrusions protruding from the first side and the second side of the rectangular-shaped portion, and the plurality of contact holes overlaps the plurality of protrusions.

In an embodiment of the present invention, the pixel circuit includes an active pattern positioned on a substrate, and a connecting member electrically connected to a conductive region included in the active pattern, and the pixel electrode is directly connected to the connecting member through the plurality of contact holes.

In an embodiment of the present invention, among the plurality of contact holes positioned between a first sub-pixel and a second sub-pixel neighboring the first sub-pixel of the plurality of sub-pixels, the contact hole connected to the pixel electrode of the first sub-pixel and the contact hole connected to the pixel electrode of the second sub-pixel are aligned with each other in the first direction.

In an embodiment of the present invention, among the plurality of contact holes positioned between the first sub-pixel and the second sub-pixel, the contact hole connected to the pixel electrode of the first sub-pixel and the contact hole connected to the pixel electrode of the second sub-pixel are alternately arranged in the second direction and not aligned in the first direction.

In an embodiment of the present invention, the interval between the plurality of second contact holes arranged along the second side is less than or equal to the length of the first side.

In an embodiment of the present invention, each of the plurality of sub-pixels has a light emitting region, and the plurality of contact holes overlaps the light emitting region.

In an embodiment of the present invention, the plurality of contact holes is positioned closer to an inner edge than to a center of the pixel electrode.

In an embodiment of the present invention, the pixel circuit includes an active pattern positioned on a substrate, and a connecting member electrically connected to a conductive region included in the active pattern, and the pixel circuit further includes a conductor that fills the plurality of contact holes, is positioned above the connecting member, and is electrically connected and in direct contact with the connecting member, the pixel electrode is directly connected to the conductor.

In an embodiment of the present invention, the plurality of contact holes further includes at least one center contact hole positioned on a vertical center line of the pixel electrode.

In an embodiment of the present invention, the vertical center line extends in the second direction.

In an embodiment of the present invention, each of the plurality of sub-pixels includes a light emitting diode including the pixel electrode, a light emitting layer positioned on the pixel electrode, and a common electrode positioned on the light emitting layer.

According to an embodiment of the present invention, a light source device includes: a light emitting panel including a plurality of unit pixels, wherein each of the plurality of unit pixels includes a plurality of sub-pixels, each of the plurality of sub-pixels includes a pixel electrode, the pixel electrode has a first side extending in a first direction and a second side that is longer than the first side and extends in a second direction that is different from the first direction, each pixel electrode is electrically connected to one or more pixel circuits through a plurality of contact holes and is configured to receive a data voltage, the plurality of contact holes includes one or more first contact holes and a plurality of second contact holes, wherein the one or more first contact holes are arranged along the first side of the pixel electrode, and the plurality of second contact holes are arranged along the second side of the pixel electrode, wherein a number of second contact holes of the plurality of second contact holes is greater than a number of the one or more first contact holes that are arranged along the first side, and the one or more pixel circuits are connected to one data line and can transmit the same data voltage to the pixel electrode through the plurality of contact holes.

In an embodiment of the present invention, each of the plurality of sub-pixels has a light emitting region, and the plurality of contact holes do not overlap the light emitting region.

In an embodiment of the present invention, the pixel circuit includes an active pattern positioned on a substrate, and a connecting member electrically connected to a conductive region included in the active pattern, and the pixel electrode is directly connected to the connecting member through the plurality of contact holes.

In an embodiment of the present invention, each of the plurality of sub-pixels has a light emitting region, and the plurality of contact holes overlaps the light emitting region.

In an embodiment of the present invention, the pixel circuit includes an active pattern positioned on a substrate, and a connecting member electrically connected to a conductive region that is included in the active pattern, the pixel circuit further includes a conductor that fills the plurality of contact holes, is positioned above the connecting member, and is directly connected to the connecting member, and the pixel electrode is directly connected to the conductor.

In an embodiment of the present invention, the plurality of contact holes further includes at least one center contact hole positioned on a vertical center line of the pixel electrode.

According to an embodiment of the present invention, a light emitting panel includes: a plurality of unit pixels, wherein each of the plurality of unit pixels includes a plurality of sub-pixels, each of the plurality of sub-pixels includes a pixel electrode, the pixel electrode has a first side extending in a first direction and a second side that is longer than the first side and extends in a second direction that intersects the first direction, wherein the pixel electrode includes protruding portions, each pixel electrode is electrically connected to one or more pixel circuits through a plurality of contact holes and is configured to receive a data voltage, the plurality of contact holes overlaps the protruding portions and includes one or more first contact holes and a plurality of second contact holes, wherein the one or more first contact holes are arranged along the first side of the pixel electrode, and the plurality of second contact holes are arranged along the second side of the pixel electrode, and the one or more pixel circuits is connected to one data line and can transmit the same data voltage to the pixel electrode through the plurality of contact holes.

### BRIEF DESCRIPTION OF THE DRAWINGS

FIG. 1 is a top plan view of a light emitting panel according to an embodiment of the present invention.

FIG. 2 is a top plan view of one unit pixel of a light emitting panel according to an embodiment of the present invention.

FIG. 3 is a top plan view of one unit pixel of a light emitting panel according to an embodiment of the present invention.

FIG. 4 is a top plan view of one unit pixel of a light emitting panel according to an embodiment of the present invention.

FIG. 5 is a top plan view of one unit pixel of a light emitting panel according to an embodiment of the present invention.

FIG. 6 is a pixel circuit diagram of one sub-pixel of a light emitting panel according to an embodiment of the present invention.

FIG. 7 is a top plan view of the pixel circuit of one sub-pixel of a light emitting panel according to an embodiment of the present invention.

FIG. 8 is a cross-sectional view of a light emitting panel shown in FIG. 7 taken along a line A1-A2.

FIG. 9 is a cross-sectional view of a light emitting panel shown in FIG. 7 taken along a line A1-A2.

FIG. 10 is a schematic drawing of a vision device including a light source device including a light emitting panel according to an embodiment of the present invention.

### DETAILED DESCRIPTION OF THE EMBODIMENTS

The present invention will be described more fully hereinafter with reference to the accompanying drawings, in which embodiments of the present invention are shown. As those skilled in the art would realize, the described embodiments may be modified in various different ways, all without departing from the spirit or scope of the present invention.

The drawings and description are to be regarded as illustrative in nature and not restrictive, and like reference numerals designate like elements throughout the specification and drawings. Thus, repetitive description of may be omitted or briefly discussed.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “on a plane” means viewing a target portion from the top, and the phrase “on a cross-section” means viewing a cross-section formed by vertically cutting a target portion from the side.

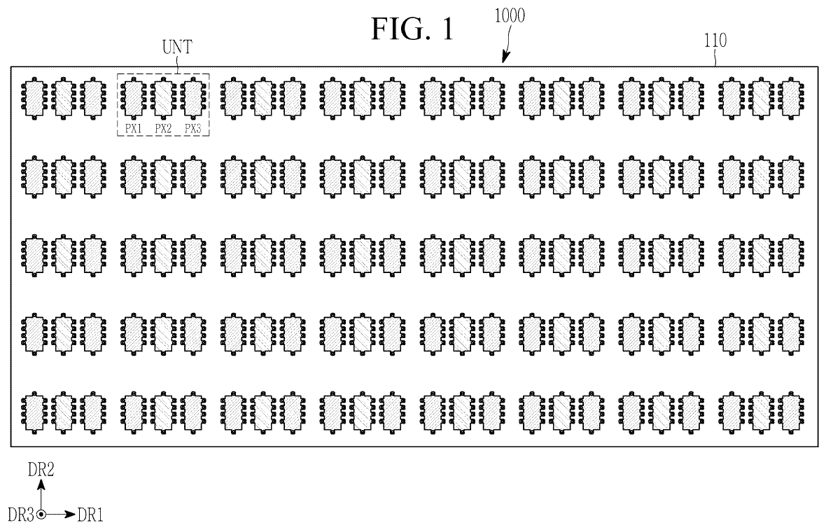

FIG. 1 is a top plan view of a light emitting panel according to an embodiment of the present invention.

Referring to FIG. 1, a light emitting panel 1000 according to an embodiment of the present invention includes a plurality of unit pixels UNT arranged on a plane parallel to a first direction DR1 and a second direction DR2. The plurality of unit pixels UNT may emit light to display images according to data signals or function as a light source by emitting light according to data signals. When functioning as the light source, the light emitting panel may be used as a light source device that emits light in a direction substantially parallel to a third direction DR3 that is substantially perpendicular to the first direction DR1 and the second direction DR2.

On a plane, the plurality of unit pixels UNT may be arranged to approximately form a matrix form on the substrate 110, but the present invention is not limited to this and may be arranged in various forms.

The unit pixel UNT may include a plurality of sub-pixels PX1, PX2, and PX3 that may emit light of different colors. For example, the plurality of sub-pixels PX1, PX2, and PX3 may include a first sub-pixel PX1 that can emit light of a first color, a second sub-pixel PX2 that can emit light of the second color, and a third sub-pixel PX3 that can emit light of the third color. However, the present invention is not limited to this, and the number of the sub-pixels included in one unit pixel UNT may be four or more. For example, the first color may be red, the second color may be blue, and the third color may be green, but they are not limited to these and may be various other basic colors.

The plurality of sub-pixels PX1, PX2, and PX3 included one unit pixel UNT, as shown in FIG. 1, may be arranged sequentially in one direction (e.g., the first direction DR1), but the present invention is not limited to this and may be arranged in various forms.

The sub-pixels PX1, PX2, and PX3 shown in FIG. 1 may correspond to light emitting regions, which are regions capable of emitting light.

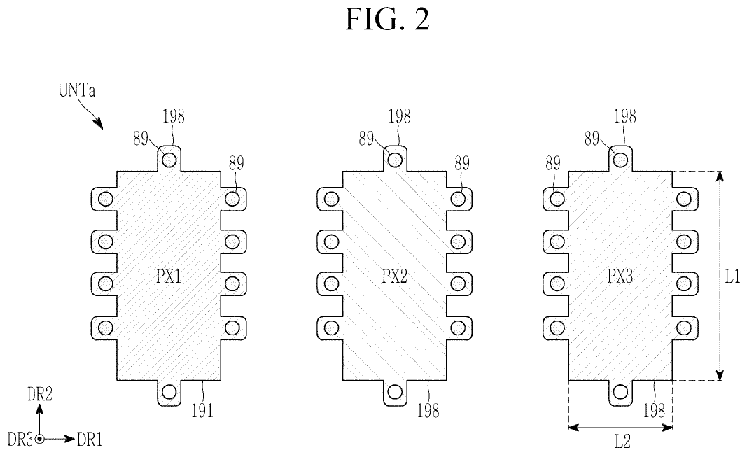

FIG. 2 is a top plan view of one unit pixel of a light emitting panel according to an embodiment of the present invention.

Referring to FIG. 2, each of the plurality of sub-pixels PX1, PX2, and PX3 included in the unit pixel UNTa according to an embodiment of the present invention may include a pixel electrode 191 capable of receiving a data voltage. The pixel electrode 191 of the plurality of sub-pixels PX1, PX2, and PX3 included in one unit pixel UNT, as shown in FIG. 1, may be arranged sequentially in one direction (e.g., the first direction DR1), but the present invention it is not limited to this and may be arranged in various forms. For example, the first sub-pixel PX1 and the second sub-pixel PX2 may be alternately arranged in the horizontal direction, and the third sub-pixels PX3 may be arranged in the vertical direction. For example, the first sub-pixel PX1 and the third sub-pixel PX3 may be alternately arranged in one diagonal direction, and the second sub-pixel PX2 and the third sub-pixel PX3 may be alternately arranged in the other diagonal direction.

The planar shape of each pixel electrode 191 may be a polygon such as a rectangular shape, or various planar shapes such as a circle or oval. FIG. 2 shows an example in which each pixel electrode 191 has a rectangular shape including a short side L2 and a long side L1 that is longer than the short side L2. When the short side L2 of each pixel electrode 191 extends in the first direction DR1 and the long side L1 extends in the second direction DR2, the plurality of sub-pixels PX1, PX2, and PX3 included in one unit pixel UNTa may be arranged in the first direction DR1.

The shape and size of the pixel electrodes 191 of the plurality of sub-pixels PX1, PX2, and PX3 included in one unit pixel UNTa may be substantially the same as each other. For example, the length of the short side L2 of the pixel electrode 191 of each sub-pixel PX1, PX2, and PX3 included in one unit pixel UNTa may be the same as each other, and the length of the long side L1 may also be the same as each other. However, the present invention is not limited to this, and the shape and size of the pixel electrode 191 of the plurality of sub-pixels PX1, PX2, and PX3 included in one unit pixel UNTa according to the light emitting characteristics of the sub-pixels PX1, PX2, and PX3 for each color may be different.

The light emitting region of each sub-pixel PX1, PX2, and PX3 may correspond to the corresponding pixel electrode 191. The light emitting region of each sub-pixel PX1, PX2, and PX3 may be the same as the region of the corresponding pixel electrode 191, and may be positioned within a region that is surrounded by the edge of the corresponding pixel electrode 191 and have edges that are parallel to the edge of the pixel electrode 191.

Each pixel electrode 191 may receive the data voltage through a plurality of contact holes 89. Among the plurality of contact holes 89 to which each pixel electrode 191 is connected, the number of contact holes 89 arranged along the long side L1 may be more than the number of contact holes 89 arranged along the short side L2. For example, the number of contact holes 89 adjacent to one short side L2 of the pixel electrode 191 may be one, and the number of contact holes 89 adjacent to the long side L1 may be two or more and may vary depending on the length of the long side L1. When there is a plurality of contact holes 89 arranged along the short side L2 or the long side L1, the interval between the plurality of contact holes 89 arranged along one direction (e.g., the first direction DR1 or the second direction DR2) may be constant.

The plurality of contact holes 89 to which each pixel electrode 191 is connected may or may not overlap the portion of the rectangular shape of the corresponding pixel electrode 191. FIG. 2 shows an example in which the plurality of contact holes 89 to which each pixel electrode 191 is connected does not overlap the portion of the rectangular shape of the corresponding pixel electrode 191. In this case, each pixel electrode 191 may include a plurality of protruding portions 198 to overlap and connect to the contact hole 89. Each protruding portion 198 may have a shape protruding in a direction that is substantially perpendicular to the direction in which the short side L2 or the long side L1 of the rectangular shape of each pixel electrode 191 on the plane is extended. For example, a protruding portion 198 that extends from the short side L2 may extend in a direction that is substantially perpendicular to the direction in which the short side L2 extends, and protruding portions 198 that extend from the long side L1 may extend in a direction that is substantially perpendicular to the direction in which the long side L1 extends.

At this time, the light emitting region of each sub-pixel PX1, PX2, and PX3 may be identical to the rectangular-shaped portion of each pixel electrode 191 or may be positioned inside the edge of the rectangular-shaped portion. The light emitting region of each sub-pixel PX1, PX2, and PX3 might not overlap the protruding portion 198.

The plurality of contact holes 89 connected to the pixel electrode 191 of the adjacent sub-pixels PX1, PX2, and PX3 may be positioned in the region between the adjacent sub-pixels PX1, PX2, and PX3 in first direction DR1 or the second direction DR2. The plurality of contact holes 89 respectively connected to two pixel electrodes 191 of the adjacent sub-pixels PX1, PX2, and PX3 positioned in the region between the adjacent sub-pixels PX1, PX2, and PX3, as shown in FIG. 2, may be adjacent in the first direction DR1 or the second direction DR2 and aligned in the first direction DR1.

Each pixel electrode 191 may receive the same data voltage through the plurality of contact holes 89 overlapping and connected thereto. The data voltages applied to the plurality of pixel electrodes 191 of the plurality of sub-pixels PX1, PX2, and PX3 included in one unit pixel UNTa may be the same or different. For example, the data voltages applied to the plurality of pixel electrodes 191 of the plurality of sub-pixels PX1, PX2, and PX3 included in one unit pixel UNTa may be independent.

The length of the short side L2 of each pixel electrode 191 may be determined according to a predetermined reference that deterioration of a luminance is not recognized on a vertical center line of the pixel electrode 191 (e.g., a center line parallel to the second direction DR2) due to a drop of the data voltage in the first direction DR1 applied through two contact holes 89 (i.e., two contact holes 89 arranged along two long sides L1 facing in the first direction DR1) facing each other to be spaced apart from each other and aligned in the first direction DR1. Under these conditions, even if the length of the long side L1 of each pixel electrode 191 is formed longer than the short side L2, the aperture of each sub-pixel PX1, PX2, and PX3 may be enlarged without causing the luminance on the vertical center line of each pixel electrode 191 to deteriorate. Accordingly, the aperture ratio and uniformity of the light emitting panel according to the embodiment may be increased. In addition, as shown in FIG. 1, the unit pixels UNT, including the plurality of sub-pixels PX1, PX2, and PX3 that can represent various basic colors may be arranged repeatedly in a matrix form, so light of various colors, including white, may be uniformly emitted.

The interval between the plurality of contact holes 89 arranged along the long side L1 of each pixel electrode 191 may be equal to or smaller than the length of the short side L2. Accordingly, the luminance non-uniformity due to the voltage drop of each pixel electrode 191 according to the second direction DR2 may be prevented.

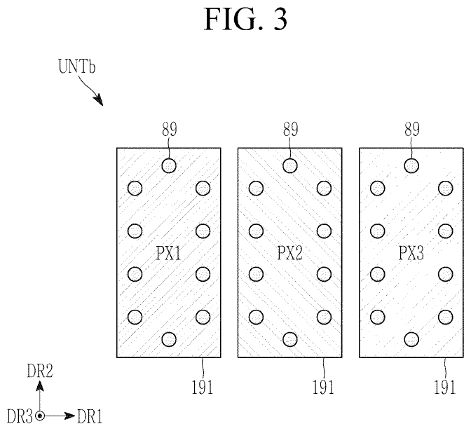

Next the light emitting panel according to an embodiment of the present invention will be described with reference to FIG. 3.

FIG. 3 is a top plan view of one unit pixel of a light emitting panel according to an embodiment of the present invention.

Referring to FIG. 3, the unit pixel UNTb included in the light emitting panel according to an embodiment of the present invention is mostly the same as the unit pixel UNTa of the light emitting panel according to the previously described embodiment, but the plurality of contact holes 89 to which each pixel electrode 191 is connected may overlap the rectangular-shaped portion of the corresponding pixel electrode 191. The plurality of contact holes 89 to which each pixel electrode 191 is connected may be arranged along the inner edge of the pixel electrode 191 and may be positioned closer to the inner edge than to the center of the pixel electrode 191.

In this case, each pixel electrode 191 might not include the protruding portion as in the previously described embodiment.

Since the plurality of contact holes 89 connected to the adjacent sub-pixels PX1, PX2, and PX3 are not positioned in the region between the adjacent sub-pixels PX1, PX2, and PX3 in the first direction DR1 or the second direction DR2, the interval between the pixel electrodes 191 of the adjacent sub-pixels PX1, PX2, and PX3 may be made smaller, the aperture of each sub-pixel PX1, PX2, and PX3 may be made wider, and the light emitting region of each sub-pixel PX1, PX2, and PX3 may be wider. Therefore, the light emitting aperture ratio of the light emitting panel 1000 may be increased, and light with a sufficient luminance may be emitted.

Among the plurality of contact holes 89 connected to the adjacent sub-pixels PX1, PX2, and PX3, the contact hole 89 of each sub-pixel PX1, PX2, and PX3 arranged along the adjacent long side L1, may be adjacent and substantially aligned with each other in the first direction DR1 as shown in FIG. 2.

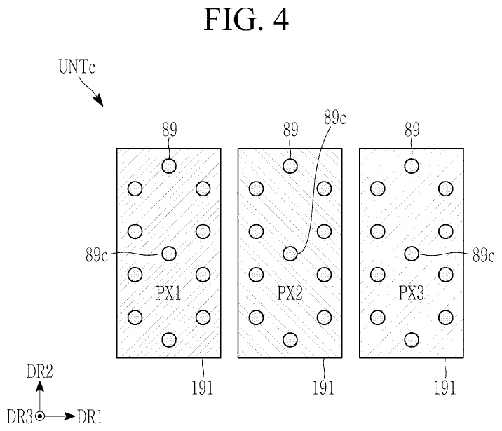

Next, a light emitting panel according to an embodiment of the present invention will be described with reference to FIG. 4.

FIG. 4 is a top plan view of one unit pixel of a light emitting panel according to an embodiment of the present invention.

Referring to FIG. 4, the unit pixel UNTc included in the light emitting panel according to an embodiment of the present invention is mostly the same as the unit pixels UNTa and UNTb of the light emitting panel according to the previously described embodiment, but it may further include at least one center contact hole 89c that is positioned approximately at the center within the region of each pixel electrode 191 and overlaps the pixel electrode 191. The center contact hole 89c may be positioned on the vertical center line of each pixel electrode 191. Each pixel electrode 191 may also receive the data voltage through the connected center contact hole 89c.

When an odd number of contact holes 89 are placed adjacent to the short side L2 of each pixel electrode 191, the contact hole 89 positioned in the center among the contact holes 89, which are adjacent to the short side L2 of each pixel electrode 191, may be aligned on the vertical center line, that extends in the second direction DR2, of each pixel electrode 191. In contrast, when there is an even number of contact holes 89 arranged along the short side L2 of each pixel electrode 191, the vertical center line of each pixel electrode 191 may pass through the middle of two contact holes 89 positioned in the center of the contact holes 89 that are adjacent to the short side L2.

Unlike shown in FIG. 4, a plurality of center contact holes 89c may be positioned inside the plane of each pixel electrode 191. In this case, the plurality of center contact holes 89c may be arranged along the vertical center line of each pixel electrode 191.

The number of center contact holes 89c placed in each of the plurality of sub-pixels PX1, PX2, and PX3 included in one unit pixel UNTc may be the same as or different from each other.

Each pixel electrode 191 may receive the same data voltage through the plurality of overlapping and connected contact holes 89 and at least one center contact hole 89c. If the data voltage is applied through the center contact hole 89c, luminance deterioration in the central part of the pixel electrode 191 due to the voltage drop may be further prevented, and light of the uniform luminance may be emitted by widening the aperture. Accordingly, the aperture ratio and uniformity of the light emitting panel according to the embodiment may be increased.

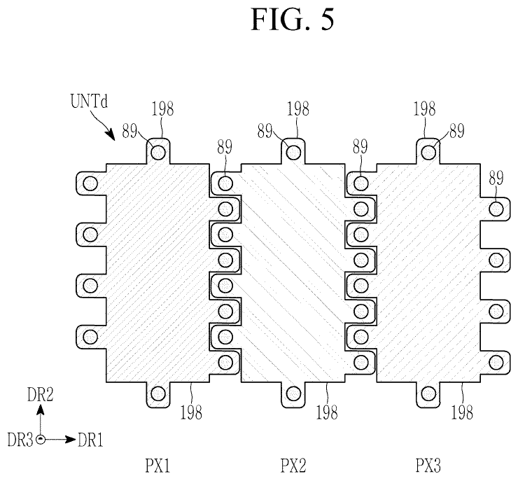

Next, a light emitting panel according to an embodiment of the present invention will be described with reference to FIG. 5.

FIG. 5 is a top plan view of one unit pixel of a light emitting panel according to an embodiment of the present invention.

Referring to FIG. 5, the unit pixel UNTd included in the light emitting panel according to an embodiment of the present invention is mostly the same as the unit pixel UNTa of the light emitting panel according to an embodiment of FIG. 2 as described above, but the plurality of contact holes 89 connected to the pixel electrodes 191 of the adjacent sub-pixels PX1, PX2, and PX3 positioned in the region between the adjacent sub-pixels PX1, PX2, and PX3 in the first direction DR1 or the second direction DR2 may be alternately arranged along the first direction DR1 or the second direction DR2.

For example, the plurality of contact holes 89 positioned in the region between two adjacent sub-pixels PX1, PX2, and PX3 in the first direction DR1 may be aligned in the second direction DR2, and the contact hole 89 connected to the pixel electrode 191 of the sub-pixel positioned on the left and the contact hole 89 connected to the pixel electrode 191 of the sub-pixel positioned on the right may be alternately positioned along the second direction DR2 and might not be aligned with each other along the first direction DR1.

The plurality of contact holes 89 positioned in the region between two adjacent sub-pixels PX1, PX2, and PX3 in the second direction DR2 may be aligned in the first direction DR1, and the contact hole 89 connected to the pixel electrode 191 of the sub-pixel positioned at the upper side on a plane and the contact hole 89 connected to the pixel electrode 191 of the sub-pixel positioned at the lower side on a plane may be positioned alternately along the first direction DR1.

Accordingly, the region between the adjacent sub-pixels PX1, PX2, and PX3 in the first direction DR1 or the second direction DR2 may be reduced, thereby the aperture of each sub-pixel PX1, PX2, and PX3 may be wider, the light emitting aperture ratio of the light emitting panel 1000 may be increased, and light with sufficient luminance may be emitted.

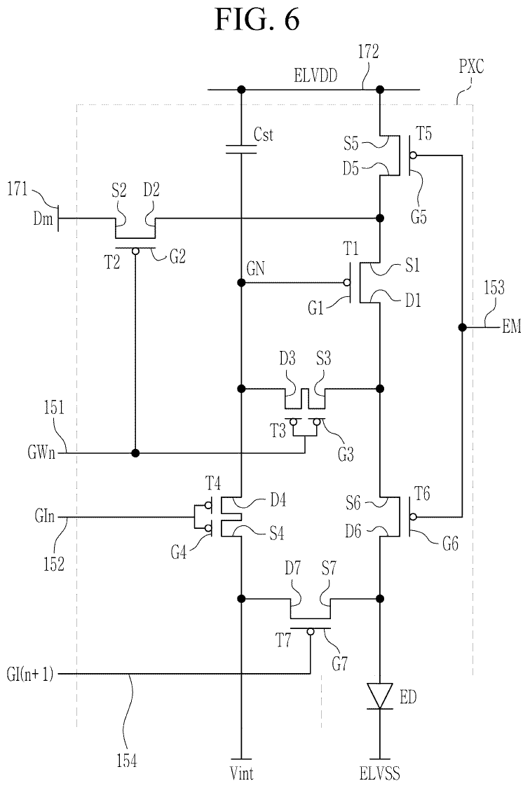

Next, a pixel circuit PXC included in or connected to the sub-pixel of the light emitting panel according to an embodiment of the present invention will be described with reference to FIG. 6.

FIG. 6 is a pixel circuit diagram of one sub-pixel of a light emitting panel according to an embodiment of the present invention.

Referring to FIG. 6, one pixel circuit PXC may include a plurality of transistors T1, T2, T3, T4, T5, T6, and T7 and a capacitor Cst, which are connected to a plurality of signal lines 151, 152, 153, 154, 171, and 172. The pixel circuit PXC is connected to the light emitting diode ED, which is a light-emitting element, to transmit a data voltage. The light emitting diode ED may include the previously described pixel electrode 191 as an anode.

The signal lines 151, 152, 153, 154, 171, and 172 may include a plurality of scan lines 151, 152, and 154, a control line 153, a data line 171, and a driving voltage line 172.

The scan lines 151, 152, and 154 may respectively transmit scan signals GWn, GIn, and GI(n+1). The scan signals GWn, GIn, and GI(n+1) may transmit a gate-on voltage and a gate-off voltage that is capable of turning the transistors T2, T3, T4, and T7 on or off.

The scan lines 151, 152, and 154 may include a first scan line 151 that is capable of transmitting the scan signal GWn, a second scan line 152 that is capable of transmitting the scan signal GIn having a gate-on voltage at a timing that is different from that of the first scan line 151, and a third scan line 154 that is capable of transmitting the scan signal GI(n+1). The second scan line 152 may transmit the gate-on voltage at a timing that is earlier than the first scan line 151. For example, when the scan signal GWn is an n-th scan signal Sn (where n is a natural number of 1 or more) among the scan signals applied during one frame, the scan signal Gln may be a front scan signal such as an (n−1)-th scan signal S(n−1) and the like, and the scan signal GI(n+1) may be the n-th scan signal Sn. However, the present embodiment is not limited thereto, and the scan signal GI(n+1) may be a different from the n-th scan signal Sn.

The control line 153 may transmit a control signal that can control the light emission of the light emitting diode ED. The light emission control signal may transmit the gate-on voltage and the gate-off voltage.

A data line 171 may transmit a data signal Dm, and a driving voltage line 172 may transmit a driving voltage ELVDD. The data signal Dm may have other voltage levels according to the image signal input to the display device, and the driving voltage ELVDD may have a substantially constant level.

The plurality of transistors T1, T2, T3, T4, T5, T6, and T7 included in one pixel PX may include a first transistor T1, a second transistor T2, a third transistor T3, a fourth transistor T4, a fifth transistor T5, a sixth transistor T6, and a seventh transistor T7.

The first scan line 151 may transmit the scan signal GWn to the second transistor T2 and the third transistor T3. The second scan line 152 may transmit the scan signal GIn to the fourth transistor T4. The third scan line 154 may transmit the scan signal GI (n+1) to the seventh transistor T7, and the control line 153 may transmit the control signal EM to the fifth transistor T5 and the sixth transistor T6.

A gate electrode G1 of the first transistor T1 is connected to one terminal Cst1 of the capacitor Cst through a driving gate node GN. A source electrode S1 of the first transistor T1 is connected to the driving voltage line 172 via the fifth transistor T5, and a drain electrode D1 of the first transistor Tl is connected to an anode of the light emitting diode ED via the sixth transistor T6.

The gate electrode of the second transistor T2 is connected to the scan line 151, and the source electrode of the second transistor T2 is connected to the data line 171. The drain electrode of the second transistor T2 is connected to the source electrode of the first transistor T1 via the fifth transistor T5 while being connected to the driving voltage line 172.

The gate electrode of the third transistor T3 may be connected to the scan line 151, and the source electrode of the third transistor T3 may be connected to the anode of the light emitting diode ED via the sixth transistor T6 while being connected to the drain electrode of the first transistor T1. The drain electrode D3 of the third transistor T3 is connected to the drain electrode D4 of the fourth transistor T4, one end of capacitor Cst, and the gate electrode G1 of the first transistor T1.

The gate electrode G4 of the fourth transistor T4 is connected to the scan line 152. The source electrode S4 of the fourth transistor T4 is connected to the initialization voltage (Vint) terminal, and the drain electrode D4 of the fourth transistor T4 is connected to one end of the capacitor Cst and the gate electrode G1 of the first transistor T1 via the drain electrode D3 of the third transistor T3. The fourth transistor T4 may be turned on according to the scan signal GIn received through the scan line 152 to transfer the initialization voltage Vint to the gate electrode G1 of the first transistor T1 to perform an initialization operation of initializing the voltage of the gate electrode G1 of the first transistor T1.

The gate electrode G5 of the fifth transistor T5 is connected to the control line 153. The source electrode S5 of the fifth transistor T5 is connected to the driving voltage line 172, and the drain electrode D5 of the fifth transistor T5 is connected to the source electrode S1 of the first transistor T1 and the drain electrode D2 of the second transistor T2.

The gate electrode G6 of the sixth transistor T6 is connected to the control line 153. The source electrode S6 of the sixth transistor T6 is connected to the drain electrode D1 of the first transistor T1 and the source electrode S3 of the third transistor T3, and the drain electrode D6 of the sixth transistor T6 is electrically connected to the anode of the light emitting diode ED. The fifth transistor T5 and the sixth transistor T6 are simultaneously turned on depending on the light emission control signal EM that is transmitted through the control line 153, whereby the driving voltage ELVDD may be compensated through the diode-connected first transistor T1 and transmitted to the light emitting diode ED.

The gate electrode G7 of the seventh transistor T7 is connected to the scan line 154. The source electrode S7 of the seventh transistor T7 is connected to the drain electrode D6 of the sixth transistor T6 and the anode of the light emitting diode ED, and the drain electrode D7 of the seventh transistor T7 is connected to the initialization voltage Vint terminal and the source electrode S4 of the fourth transistor T4.

One end of the capacitor Cst is connected to the gate electrode G1 of the first transistor T1 as described previously, and the other end of the capacitor Cst is connected to the driving voltage line 172. The cathode of the light emitting diode ED is connected to a common voltage ELVSS terminal that transmits the common voltage (ELVSS), so that the common voltage ELVSS may be applied.

The structure of the pixel circuit PXC according to an embodiment of the present invention is not limited to the structure shown in FIG. 6 and may be altered in various ways.

The pixel electrode 191 of each sub-pixel PX1, PX2, and PX3 described above may be connected to one pixel circuit PXC and may receive a data voltage, or may be connected to a plurality of pixel circuits PXC and receive a data voltage.

For example, in the embodiment shown in FIG. 1 to FIG. 5 that were previously described, the plurality of contact holes 89 and/or the center contact hole 89c where the pixel electrode 191 of each sub-pixel PX1, PX2, and PX3 is connected may be connected to one pixel circuit PXC corresponding to each sub-pixel PX1, PX2, and PX3, thereby receiving the same data voltage. For example, the pixel electrode 191 of each sub-pixel PX1, PX2, and PX3 may receive one data voltage transmitted through the pixel circuit PXC that is connected to one data line through the plurality of contact holes 89 and/or the center contact hole 89c. In this case, the plurality of contact holes 89 and/or the center contact hole 89c where the pixel electrode 191 of each sub-pixel PX1, PX2, and PX3 is connected may all be connected to one first transistor T1 and one sixth transistor T6 included in one pixel circuit PXC corresponding to each sub-pixel PX1, PX2, and PX3. According to an embodiment of the present invention, the plurality of contact holes 89 and/or the center contact hole 89c to which the pixel electrode 191 of each sub-pixel PX1, PX2, and PX3 is connected may be respectively connected to the plurality of first transistors T1 and the plurality of sixth transistors T6 included in one pixel circuit PXC corresponding to each sub-pixel PX1, PX2, and PX3, respectively.

According to an embodiment of the present invention, in the embodiment shown in FIG. 1 to FIG. 5, at least two or more of the plurality of contact holes 89 and the center contact hole 89c where the pixel electrode 191 of each sub-pixel PX1, PX2, and PX3 is connected may be connected to two or more different pixel circuits PXC corresponding to each sub-pixel PX1, PX2, and PX3 to receive one data voltage. In this case, the plurality of pixel circuits PXC transmitting the data voltage to the pixel electrode 191 of one sub-pixel PX1, PX2, and PX3 through two or more of the contact holes 89 and/or the center contact hole 89c may receive the signal through the same signal lines 151, 152, 153, 154, 171, and 172 to be simultaneously driven. For example, the pixel electrode 191 of each sub-pixel PX1, PX2, and PX3 may receive one data voltage that is transmitted through the plurality of pixel circuits PXC connected to one data line through the plurality of contact holes 89 and/or the center contact hole 89c.

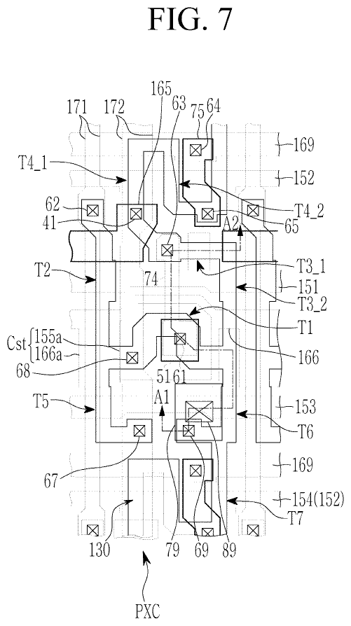

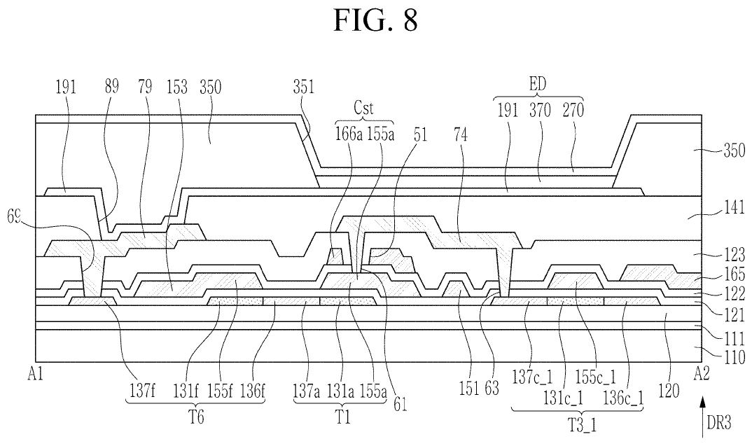

The planar structure of the pixel circuit included in the light emitting panel according to an embodiment of the present invention will be described with reference to FIG. 7 and FIG. 8 along with the drawings described above.

FIG. 7 is a top plan view of the pixel circuit of one sub-pixel of a light emitting panel according to an embodiment of the present invention. FIG. 8 is a cross-sectional view of a light emitting panel shown in FIG. 7 taken along a line A1-A2.

Referring to FIG. 7 and FIG. 8, a barrier layer 111, which is an insulating layer, may be positioned on a substrate 110, and a buffer layer 120, which is an insulating layer, may be positioned on the barrier layer 111. At least one of the barrier layer 111 or buffer layer 120 may be omitted.

An active pattern 130 is positioned on the buffer layer 120. The active pattern 130 may include a channel region and a conductive region forming each channel of the plurality of transistors T1, T2, T3_1, T3_2, T4_1, T4_2, T5, T6, and T7. The conductive region of the active pattern 130 may include source regions 136c_1 and 136f and drain regions 137c_1, 137a, and 137f of each transistor T1, T2, T3_1, T3_2, T4_1, T4_2, T5, T6, and T7. The terms “source region” and “drain region” are used to distinguish conductive regions that are positioned on opposing sides of each channel region as a reference, and the terms “source region” and “drain region” may be used interchangeably.

The third transistor T3 described above may include two third transistors T3_1 and T3_2 which are coupled in series and include the same gate electrode, and the fourth transistor T4 described above may include two fourth transistors T4_1 and T4_2 which are coupled in series and include the same gate electrode.

The active pattern 130 may include, for example, amorphous silicon, polycrystalline silicon, or oxide semiconductor.

A first insulating layer 121 may be positioned on the active pattern 130, and a first conductive layer may be positioned on the first insulating layer 121. The first conductive layer may include the plurality of scan lines 151, 152, and 154 described above, the control line 153, and a driving gate electrode 155a.

A second insulating layer 122 may be positioned on the first conductive layer and the first insulating layer 121, and the second conductive layer may be positioned on the second insulating layer 122. The second conductive layer may include a storage line 166 and an initialization voltage line 169 that transmits the initialization voltage. The storage line 166 may include an extension 166a that overlaps the driving gate electrode 155a.

The second conductive layer may further include a shield pattern 165. The shield pattern 165 may be positioned between the scan line 151 and the scan line 152.

A third insulating layer 123 may be positioned above the second conductive layer and the second insulating layer 122.

At least one of the barrier layer 111, the buffer layer 120, the first insulating layer 121, the second insulating layer 122, or the third insulating layer 123 may include an inorganic insulating material and/or an organic insulating material such as silicon oxide, silicon nitride, silicon oxynitride, oxidation aluminum, etc.

Some or all of the first insulating layer 121, the second insulating layer 122, and the third insulating layer 123 may include a plurality of contact holes 41, 61, 62, 63, 64, 65, 67, 68, and 69.

A third conductive layer may be positioned on the third insulating layer 123. The third conductive layer may include a plurality of connecting members 74, 75, and 79 connected to the conductive region of the active pattern 130, a data line 171, and a driving voltage line 172.

The data line 171 and the driving voltage line 172 may intersect with the plurality of scan lines 151, 152, and 154. The extension 166a of the storage line 166 may be connected to the driving voltage line 172 through the contact hole 68 to receive the driving voltage ELVDD.

The driving voltage line 172 may be electrically connected to the shield pattern 165 through the contact hole 41 to transmit the driving voltage ELVDD to the shield pattern 165. The shield pattern 165 may be omitted.

The first transistor T1 includes a channel region 131f, a source region, and a drain region 137a, and the driving gate electrode 155a may be connected to the connecting member 74 through the contact hole 61. The contact hole 61 may be positioned within a hole 51 that is included in the extension 166a.

The source region of the second transistor T2 is connected to data line 171 through contact hole 62, and the drain region is connected to the source region of the first transistor T1.

The third transistor T3_1 includes a channel region 131c_1, a source region 136c_1, a drain region 137c_1, and a gate electrode 155c_1, and the drain region 137c_1 may be connected to the connecting member 74 through the contact hole 63.

The drain region of the fourth transistor T4_1 is connected to the drain region 137c_1 of the third transistor T3_1 and is connected to the connecting member 74 through the contact hole 63. The drain region of the fourth transistor T4_2 is connected to the source region of the fourth transistor T4_1, and the source region of the fourth transistor T4_2 is connected to the connecting member 75 through the contact hole 65. The connecting member 75 may be electrically connected to the initialization voltage line 169 through the contact hole 64.

The source region of the fifth transistor T5 is electrically connected to the driving voltage line 172 through the contact hole 67, and the drain region is connected to the source region of the first transistor T1.

The sixth transistor T6 includes a channel region 131f, a source region 136f, a drain region 137f, and a gate electrode 155f, and the source region 136f is connected to the drain region 137a of the first transistor T1, and the drain region 137f is connected to the connecting member 79 through the contact hole 69.

The source region of the seventh transistor T7 is connected to the drain region 137f of the sixth transistor T6, and the drain region of the seventh transistor T7 is connected to the connecting member 75 through the contact hole 65 to receive the initialization voltage.

The capacitor Cst may include the driving gate electrode 155a and the extension 166a of the storage line 166 as two terminals that overlap each other with the second insulating layer 122 disposed therebetween.

At least one of the first conductive layer, the second conductive layer, or the third conductive layer may include at least one of metals such as copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), alloys thereof, etc.

A fourth insulating layer 141 may be positioned above the third conductive layer. The fourth insulating layer 141 may include an inorganic insulating material and/or an organic insulating material such as polyimide, acryl-based polymer, or siloxane-based polymer.

A plurality of pixel electrodes 191 may be positioned on the fourth insulating layer 141. The pixel electrode 191 may be electrically connected to the connecting member 79 through the contact hole 89 that is formed in the fourth insulating layer 141 to receive a data voltage. As described above, one pixel electrode 191 is electrically connected to the connecting member 79 through the plurality of contact holes 89 and/or the center contact hole 89c to receive a data voltage. For example, the pixel electrode 191 may be in direct contact with and connected to the connecting member 79 through the contact hole 89 and/or the center contact hole 89c.

A fifth insulating layer 350 (e.g., a pixel defining layer) may be positioned on the fourth insulating layer 141. The fifth insulating layer 350 may have an opening 351 that is positioned to overlap the pixel electrode 191. The fifth insulating layer 350 may include organic insulating materials such as polyacryl-based resin and polyimide-based resin.

A light emitting layer 370 is positioned on the pixel electrode 191. The light emitting layer 370 may include a portion that is positioned within the opening 351 of the fifth insulating layer 350. The light emitting layer 370 may include an organic light emitting material or an inorganic light emitting material.

A common electrode 270 may be positioned on the light emitting layer 370. The common electrode 270 may also be formed on the fifth insulating layer 350 and continuously formed over the plurality of sub-pixels PX1, PX2, and PX3. The common electrode 270 may include a conductive transparent material.

The pixel electrode 191, the light emitting layer 370, and the common electrode 270 may together form the light emitting diode ED, and one of the pixel electrode 191 or the common electrode 270 may be a cathode and the other may be an anode.

The opening 351 of the fifth insulating layer 350 may define the light emitting region of each sub-pixel PX1, PX2, and PX3. As shown in FIG. 8, the opening 351 may be positioned inside the edge of each pixel electrode 191, or alternatively, the opening 351 may be substantially aligned with the edge of each pixel electrode 191.

Referring to FIG. 8, the contact hole 89 might not overlap the light emitting region of the light emitting diode ED in the third direction DR3. In this case, the contact hole 89, in the embodiment of FIG. 2 or FIG. 5 described above, overlaps the protruding portion 198 of the pixel electrode 191, so that the protruding portion 198 of the pixel electrode 191 may be electrically connected to the connecting member 79 through the contact hole 89 and may be electrically connected to the sixth transistor T6. In the present embodiment, the top of the contact hole 89 may be covered by the fifth insulating layer, which is a pixel defining layer.

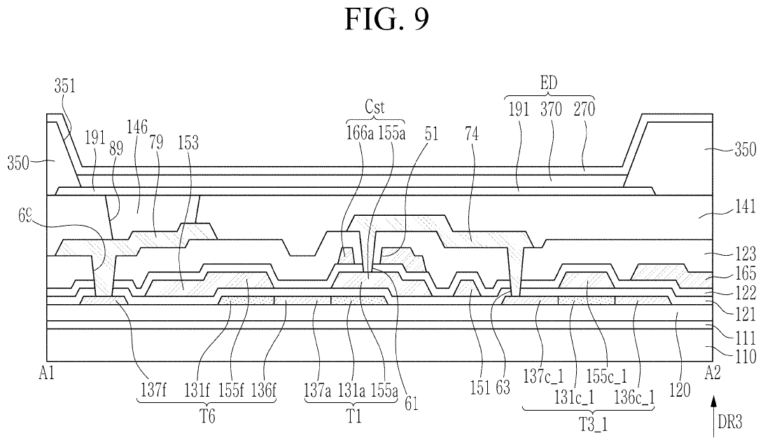

Next, the light emitting panel according to an embodiment of the present invention will be described with reference to FIG. 9 along with FIG. 7 and FIG. 8.

FIG. 9 is a cross-sectional view of a light emitting panel shown in FIG. 7 taken along a line A1-A2.

Referring to FIG. 9, the light emitting panel according to an embodiment of the present invention is mostly the same as the light emitting panel according to the embodiment shown in FIG. 7 and FIG. 8 as above described, but the pixel electrode 191 may be indirectly electrically connected to the connecting member 79 through another conductor, and is not directly contacting the connecting member 79 through the contact hole 89 and/or the center contact hole 89c.

For example, the contact hole 89 and/or the center contact hole 89c may be filled with a conductor 146 that is formed before stacking the pixel electrode 191, and the pixel electrode 191 may be electrically connected to the connecting member 79 by being in contact with the conductor 146. The conductor 146 may be electrically connected by being in direct contact with the connecting member 79. Accordingly, the pixel electrode 191 may be electrically connected to the connecting member 79 through the conductor 146 and receive the data voltage.

The upper surface of the fourth insulating layer 141, where the contact hole 89 and/or the center contact hole 89c is formed, and the upper surface of the conductor 146 are substantially the same height, so that a planarized surface may be formed. For example, the upper surface of the fourth insulating layer 141 and the conductor 146 may be substantially coplanar. For this, in the manufacturing process of the light emitting panel, after forming the contact hole 89 and/or the center contact hole 89c in the fourth insulating layer 141, a conductive material may be stacked and the upper surface thereof may be polished, so that the conductor 146 remains only in the contact hole 89 and/or the center contact hole 89c, and then the upper surface of the substrate 110 may be flat. Next, when the pixel electrode 191 is formed on the upper surface of the substrate 110, the lower and upper surfaces of the pixel electrode 191 may be flat. Accordingly, the pixel electrode 191 and the light emitting diode ED may be formed on the flat surface without being curved, thereby preventing the occurrence of defects in the light emitting diode ED.

Even though the contact hole 89 and/or the center contact hole 89c overlaps the opening of each sub-pixel, which is the light emitting region, defects of the light emitting diode ED may be prevented. Thus, like the light emitting panel according to the embodiment shown in FIG. 3 or FIG. 4 described above, the plurality of contact holes 89 and the center contact hole 89c may be placed in the portion of the rectangular shape of the pixel electrode 191, that is, in the portion that overlaps the light emitting region. Accordingly, the interval between the pixel electrodes 191 of the adjacent sub-pixels may become smaller, the opening of each sub-pixel may become wider, and the light emitting region of each sub-pixel may become larger. Therefore, the light emitting aperture ratio of the light emitting panel may be increased and light with sufficient luminance may be emitted.

According to an embodiment of the present invention, the contact hole 89 and/or the center contact hole 89c may overlap the light emitting region of the light emitting diode ED in the third direction DR3, and the light emitting layer 370 may cover the top of the contact hole 89 and/or the center contact hole 89c without being covered by the fifth insulating layer, which is a pixel defining layer.

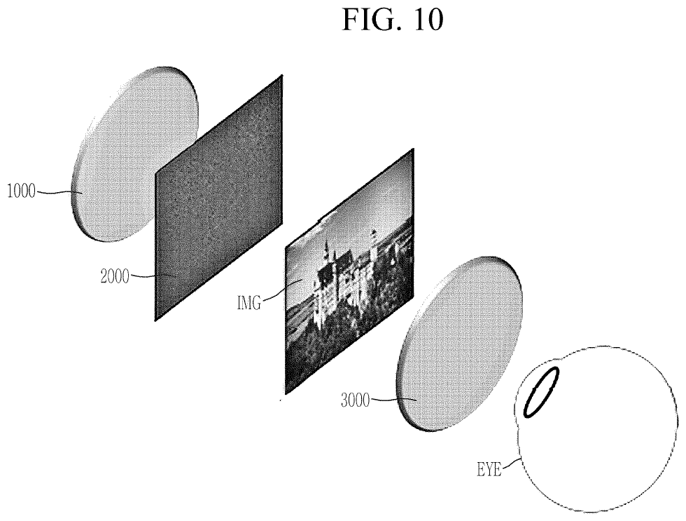

Next, a vision device including a light source device including the light emitting panel according to an embodiment of the present invention will be described with reference to FIG. 10.

FIG. 10 is a schematic drawing of a vision device including a light source device including a light emitting panel according to an embodiment of the present invention.

Referring to FIG. 10, the vision device comprising the light source device including the light emitting panel according to an embodiment of the present invention may be a variety of display devices capable of implementing extended reality (XR) such as a holographic display, augmented reality (AR), virtual reality (VR), and mixed reality (MR). For example, the vision device according to an embodiment of the present invention may include the light emitting panel 1000 according to the embodiment as the light source, and may include an optical modulation unit 2000 capable of modulating light from the light emitting panel 1000, and an alternative lens 3000 capable of changing the optical path of an image IMG of light passing through the optical modulation unit 2000 to enter the user's eye (EYE).

When the light emitting panel 1000 according to an embodiment of the present invention is used as a light source, as described above, it is possible to supply light with an overall uniform and high aperture ratio, thereby increasing the quality of the vision device.

While the present invention has been described with reference to exemplary embodiments thereof, it will be understood by those of ordinary skill in the art that various changes in form and details may be made thereto without departing from the spirit and scope of the present invention.

### DESCRIPTION OF SYMBOLS

41, 61, 62, 63, 64, 65, 67, 68, 69, 89, 89c: contact hole
74, 75, 79: connecting member
110: substrate
111: barrier layer
120: buffer layer
121, 122, 123, 141, 350: insulating layer
130: active pattern
151, 152, 154: scan line
153: control line
155a: driving gate electrode
155f: gate electrode
171: data line
172: driving voltage line
191: pixel electrode
198: protruding portion
270: common electrode
370: light emitting layer
1000: light emitting panel
2000: optical modulation unit
3000: alternative lens
PX1, PX2, PX3: sub-pixel
PXC: pixel circuit
UNT, UNTa, UNTb, UNTc, UNTd: unit pixel

What is claimed is:

1. A light emitting panel comprising:
a plurality of unit pixels,
wherein each of the plurality of unit pixels includes a plurality of sub-pixels,
each of the plurality of sub-pixels includes a pixel electrode,
the pixel electrode has a first side extending in a first direction and a second side that is longer than the first side and extends in a second direction that is different from the first direction,
each pixel electrode is electrically connected to one or more pixel circuits through a plurality of contact holes and is configured to receive a data voltage,
the plurality of contact holes includes one or more first contact holes and a plurality of second contact holes, wherein the one or more first contact holes are arranged along the first side of the pixel electrode, and the plurality of second contact holes are arranged along the second side of the pixel electrode, wherein a number of second contact holes of the plurality of second contact holes is greater than a number of the one or more first contact holes that are arranged along the first side, and
the one or more pixel circuits is connected to one data line and can transmit the same data voltage to the pixel electrode through the plurality of contact holes.

2. The light emitting panel of claim 1, wherein:
the plurality of sub-pixels each has a light emitting region, and
the plurality of contact holes do not overlap the light emitting region.

3. The light emitting panel of claim 2, wherein:
the pixel electrode includes a rectangular-shaped portion and a plurality of protrusions protruding from the first side and the second side of the rectangular-shaped portion,
and the plurality of contact holes overlaps the plurality of protrusions.

4. The light emitting panel of claim 3, wherein:
the pixel circuit includes an active pattern positioned on a substrate, and a connecting member electrically connected to a conductive region included in the active pattern, and
the pixel electrode is directly connected to the connecting member through the plurality of contact holes.

5. The light emitting panel of claim 1, wherein:
among the plurality of contact holes positioned between a first sub-pixel and a second sub-pixel neighboring the first sub-pixel of the plurality of sub-pixels, the contact hole connected to the pixel electrode of the first sub-pixel and the contact hole connected to the pixel electrode of the second sub-pixel are aligned with each other in the first direction.

6. The light emitting panel of claim 1, wherein:
among the plurality of contact holes positioned between the first sub-pixel and the second sub-pixel, the contact hole connected to the pixel electrode of the first sub-pixel and the contact hole connected to the pixel electrode of the second sub-pixel are alternately arranged in the second direction and not aligned in the first direction.

7. The light emitting panel of claim 1, wherein:
the interval between the plurality of second contact holes arranged along the second side is less than or equal to the length of the first side.

8. The light emitting panel of claim 1, wherein:
each of the plurality of sub-pixels has a light emitting region, and
the plurality of contact holes overlaps the light emitting region.

9. The light emitting panel of claim 8, wherein:
the plurality of contact holes is positioned closer to an inner edge than to a center of the pixel electrode.

10. The light emitting panel of claim 8, wherein:
the pixel circuit includes an active pattern positioned on a substrate, and a connecting member electrically connected to a conductive region included in the active pattern,
the pixel circuit further includes a conductor that fills the plurality of contact holes, is positioned above the connecting member, and is electrically connected and in direct contact with the connecting member, and
the pixel electrode is directly connected to the conductor.

11. The light emitting panel of claim 1, wherein:
the plurality of contact holes further includes at least one center contact hole positioned on a vertical center line of the pixel electrode.

12. The light emitting panel of claim 11, wherein:
the vertical center line extends in the second direction.

13. The light emitting panel of claim 1, wherein:
each of the plurality of sub-pixels includes a light emitting diode including the pixel electrode, a light emitting layer positioned on the pixel electrode, and a common electrode positioned on the light emitting layer.

14. A light source device comprising:
a light emitting panel including a plurality of unit pixels,
wherein each of the plurality of unit pixels includes a plurality of sub-pixels,
each of the plurality of sub-pixels includes a pixel electrode,
the pixel electrode has a first side extending in a first direction and a second side that is longer than the first side and extends in a second direction that is different from the first direction,
each pixel electrode is electrically connected to one or more pixel circuits through a plurality of contact holes and is configured to receive a data voltage,
the plurality of contact holes includes one or more first contact holes and a plurality of second contact holes, wherein the one or more first contact holes are arranged along the first side of the pixel electrode, and the plurality of second contact holes are arranged along the second side of the pixel electrode, wherein a number of second contact holes of the plurality of second contact holes is greater than a number of the one or more first contact holes that are arranged along the first side, and
the one or more pixel circuits are connected to one data line and can transmit the same data voltage to the pixel electrode through the plurality of contact holes.

15. The light source device of claim 14, wherein:
each of the plurality of sub-pixels has a light emitting region, and
the plurality of contact holes do not overlap the light emitting region.

16. The light source device of claim 15, wherein:
the pixel circuit includes an active pattern positioned on a substrate, and a connecting member electrically connected to a conductive region included in the active pattern, and
the pixel electrode is directly connected to the connecting member through the plurality of contact holes.

17. The light source device of claim 14, wherein:
each of the plurality of sub-pixels has a light emitting region, and
the plurality of contact holes overlaps the light emitting region.

18. The light source device of claim 17, wherein:
the pixel circuit includes an active pattern positioned on a substrate, and a connecting member electrically connected to a conductive region that is included in the active pattern,
the pixel circuit further includes a conductor that fills the plurality of contact holes, is positioned above the connecting member, and is directly connected to the connecting member, and
the pixel electrode is directly connected to the conductor.

19. The light source device of claim 14, wherein:
the plurality of contact holes further includes at least one center contact hole positioned on a vertical center line of the pixel electrode.

20. A light emitting panel comprising:
a plurality of unit pixels,
wherein each of the plurality of unit pixels includes a plurality of sub-pixels,
each of the plurality of sub-pixels includes a pixel electrode,
the pixel electrode has a first side extending in a first direction and a second side that is longer than the first side and extends in a second direction that intersects the first direction, wherein the pixel electrode includes protruding portions,
each pixel electrode is electrically connected to one or more pixel circuits through a plurality of contact holes and is configured to receive a data voltage,
the plurality of contact holes overlaps the protruding portions and includes one or more first contact holes and a plurality of second contact holes, wherein the one or more first contact holes are arranged along the first side of the pixel electrode, and the plurality of second contact holes are arranged along the second side of the pixel electrode, and
the one or more pixel circuits is connected to one data line and can transmit the same data voltage to the pixel electrode through the plurality of contact holes.
